(19) United States
(12) Patent Application Publication
(10) Pub. No.: US 2011/0221046 A1
(43) Pub. Date: Sep. 15, 2011

(54) SEMICONDUCTOR ASSEMBLY PACKAGE HAVING SHIELDING LAYER AND METHOD THEREFOR

(75) Inventor: JUN-YI XIAO, Zhongshan City (CN)

(73) Assignees: Ambit Microsystems (Zhongshan) LTD., Zhongshan City (CN); HON HAI PRECISION INDUSTRY CO., LTD., Tu-Cheng (TW)

(21) Appl. No.: 13/034,616

(22) Filed: Feb. 24, 2011

(30) Foreign Application Priority Data
Mar. 11, 2010 (CN) 201010122286.2

(51) Int. Cl. H01L 23/552; H01L 21/56

(52) U.S. Cl. 257/659; 438/113; 257/E23.114; 257/E21.502

(57) ABSTRACT

A semiconductor assembly package includes a package unit, a shielding layer and a protection layer. The package unit includes a semiconductor assembly, a daughter substrate and a mold compound. The semiconductor assembly is disposed on and electrically connected to the daughter substrate. The daughter substrate includes a metal portion grounded. The mold compound encapsulates the semiconductor assembly and the daughter substrate to expose the metal portion out of the package unit. The shielding layer is applied to the package unit and electrically connected to the metal portion, to provide electromagnetic shielding for the semiconductor assembly. The non-conductive protection layer is covered on the shielding layer.

### BACKGROUND

1. Technical Field

The present disclosure relates to a semiconductor assembly package, and more particularly to a semiconductor assembly package having an integrated electromagnetic shielding layer.

2. Description of Related Art

Electromagnetic shielding is required on semiconductor assemblies in order to minimize electromagnetic interference (EMI) from the semiconductor assembly. RF shielding is further required to prevent RF radiation from external sources from interfering with operation of the semiconductor assembly.

Electromagnetic shielding is generally a metal enclosure which encloses the semiconductor assembly attached on a mother board of a product. However, shield additionally attached on the mother board requires additional board space to enlarge the size of the product.

Therefore, a need exists in the industry to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of an embodiment of a semiconductor assembly package in accordance with the present disclosure;

FIG. 2 is a cross-sectional view of the embodiment of attaching a semiconductor assembly to a daughter substrate in accordance with the present disclosure;

FIG. 3 is a cross-sectional view of the embodiment of encapsulating the semiconductor and the daughter substrate of FIG. 2 with a mold compound;

FIG. 4 is a cross-sectional view of the embodiment of cutting the encapsulated body of FIG. 3 into two pieces; and

FIG. 5 is a flowchart of the embodiment of manufacturing the semiconductor assembly package in accordance with the present disclosure.

FIG. 6 is a flowchart of the embodiment of disposing a plurality of semiconductor assemblies on a mother substrate in accordance with the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

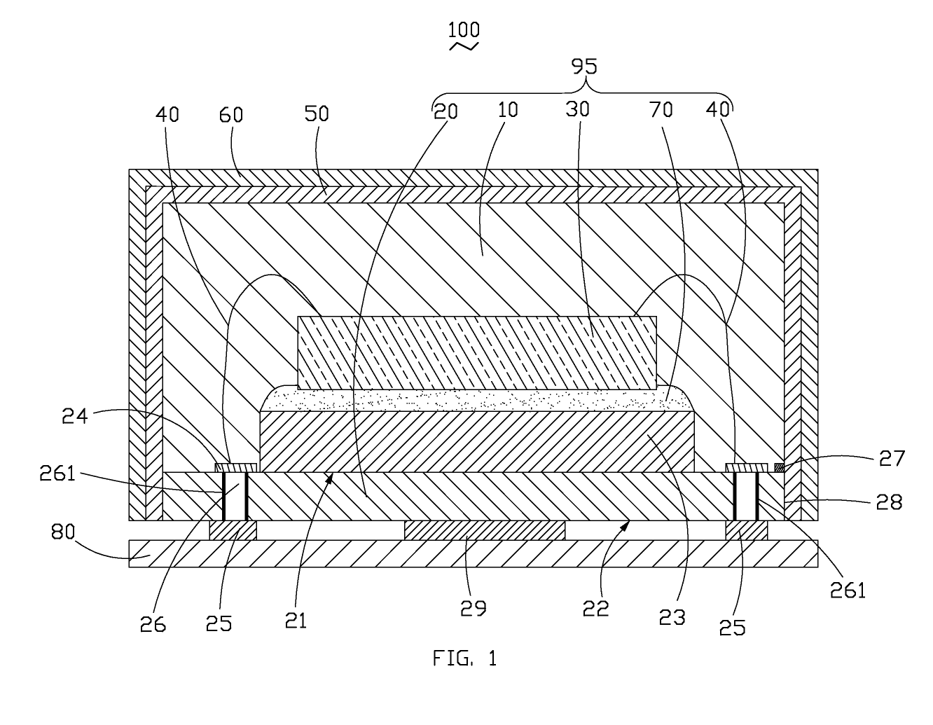

FIG. 1 is a cross-sectional view of a semiconductor assembly package 100 in accordance with the present disclosure. The semiconductor assembly package 100 comprises a package unit 95, a shielding layer 50 and a protection layer 60. The package unit 95 comprises a mold compound 10, a daughter substrate 20, a semiconductor assembly 30 encapsulated by the mold compound 10 and a plurality of bonding wires 40.

The daughter substrate 20 comprises a first surface 21, a second surface 22 opposite to the first surface 21, a seat portion 23, a plurality of first bonding pads 24, a plurality of second bonding pads 25, and a connecting portion 29. The daughter substrate 20 defines a plurality of via holes 26 passing through the first surface 21 to the second surface 22. The seat portion 23 and the plurality of first bonding pads 24 are placed on the first surface 21, and the plurality of second bonding pads 25 are placed on the second surface 22 and are in pair with the plurality of first bonding pads 24 respectively. Each of the plurality of via holes 26 electrically connects between each of the plurality of first bonding pads 24 and the corresponding second bonding pad 25. In this embodiment, a metal layer 261 (such as copper, gold, or silver) is coated on inner walls of each of the plurality of via holes 26, thus, the plurality of first bonding pads 24 electrically connect to the corresponding second bonding pads 25 via the corresponding metal layers 261. The connecting portion 29 is disposed on the second surface 22 of the daughter substrate 20 opposite to the seat portion 23 to electrically connect to a circuit (not shown) of the daughter substrate 20 as an input/output terminal of the daughter substrate 20 to input/output electrical signals.

The daughter substrate 20 is electrically mounted on a printed circuit board (PCB) 80 via the plurality of second bonding pads 25. One of the second bonding pads 25 electrically connects to a ground element (not shown) on the PCB 80. That is, one of the second bonding pads 25 is grounded and one of the first bonding pad 24 is grounded as the plurality of second bonding pads 25 are in pair with the corresponding first bonding pads 24 respectively.

The daughter substrate 20 further comprises a metal portion 27 grounded, that is, the metal portion 27 electrically connects to the second bonding pad 25 which is grounded via a metal wire (not shown), so that, the metal portion 27 is grounded. The metal portion 27 is disposed on the first surface 21 and exposed on a side edge 28 of the package unit 95. In the embodiment, the metal portion 27 is made of copper foil. In other embodiment, the daughter substrate 20 is a multilayer printed circuit board with a plurality of metal portions 27 on any copper foil layers of the daughter substrate 20, and one of the plurality of metal portions 27 is exposed on the side edge 28 of the package unit 95 and electrically connects to the second bonding pad 25 which is grounded.

The semiconductor assembly 30 is mechanically attached to and electrically connected to the daughter substrate 20. In the illustrated embodiment, the semiconductor assembly 30 is mounted on the seat portion 23 by means of an adhesive 70. The adhesive 70 may be an adhesive film, an epoxy resin, or the like, to further provide improved heat dissipation of the semiconductor assembly 30. The semiconductor assembly 30 may be a chip, a memory assembly, a logic assembly, and other like elements. It should be noted that the listing of the above types of semiconductor assembly 30 is given as an example and should not be seen as to limit the scope of the present invention.

The semiconductor assembly 30 is electrically connected to the plurality of first bonding pads 24 via the plurality of bonding wires 40 so as to electrically connect to the daughter substrate 20. It should be noted that the semiconductor assembly 30 is grounded by connecting with one of the first bonding pads 24 which is grounded. In the illustrated embodiment, each of the plurality of bonding wires 40 is a gold wire.

The mold compound 10 encapsulates the semiconductor assembly 30, the plurality of bonding wires 40 and the first surface 21 of the daughter substrate 20. In the illustrated embodiment, the mold compound 10 is made of non-conductive material, such as black gum, plastic.

The shielding layer 50 is applied to the package unit 95 and electrically connected to the metal portion 27, to provide electromagnetic shielding for the semiconductor assembly 30. In detail, the shielding layer 50 is applied to outer surface of the mold compound 10 and the side edge 28, and electrically connected to the metal portion 27 which is grounded and exposed out of the package unit 90, so that the shielding layer 50 is grounded. That is, the semiconductor assembly 30 can be shielded by connecting the shielding layer 50 with the metal portion 27. In other embodiment, the shielding layer 50 is only applied to outer surface of the mold compound 10 and electrically connects to the metal portion 27 which is grounded.

In the illustrated embodiment, the shielding layer 50 is made of metal, such as copper, nickel, chrome, gold, tin, lead, bismuth, indium, silver, and combination of these metals, which can minimize electro-magnetic interference (EMI) from the semiconductor assembly 30. The shielding layer 50 may be achieved by plating, vacuum printing, vacuum deposition, insert molding, spray coating, and the like.

The shielding layer 50 may produce a plurality of tin points adhered on the PCB 80 in soldering process, and the plurality of tin points may affect connection between the shielding layer 50 and the PCB 80. The shielding layer 50 is insulated from each of the plurality of second bonding pads 25 to avoid the plurality of tin points adhered on the PCB 80. In this embodiment, the shielding layer 50 is isolated from the plurality of second bonding pads 25.

The protection layer 60 is covered on outer surface of the shielding layer 50 to prevent short-circuit between the semiconductor assembly package 100 and other components. In addition, the protection layer 60 is isolated from each of the plurality of second bonding pads 25 to avoid affecting the second bonding pads 25 adhering on the PCB 80. The protection layer 60 is made of non-conductive material, such as plastic, rubber, lacquer, glass, and the like. In the illustrated embodiment, the protection layer 60 is made of a transparent non-conductive material, such as transparent Polyvinylcloride (PVC). The protection layer 60 may be achieved by plating, vacuum printing, vacuum deposition, insert molding, spray coating and the like.

The shielding layer 50 is directly applied to the semiconductor assembly 30 for RF shielding, thereby dispensing with an additional shielding cover to be fixed on the PCB 80 to shield the semiconductor assembly 30. That is to say, the size of the PCB 80 may be decreased and the volume of the semiconductor assembly package 100 may be minimized.

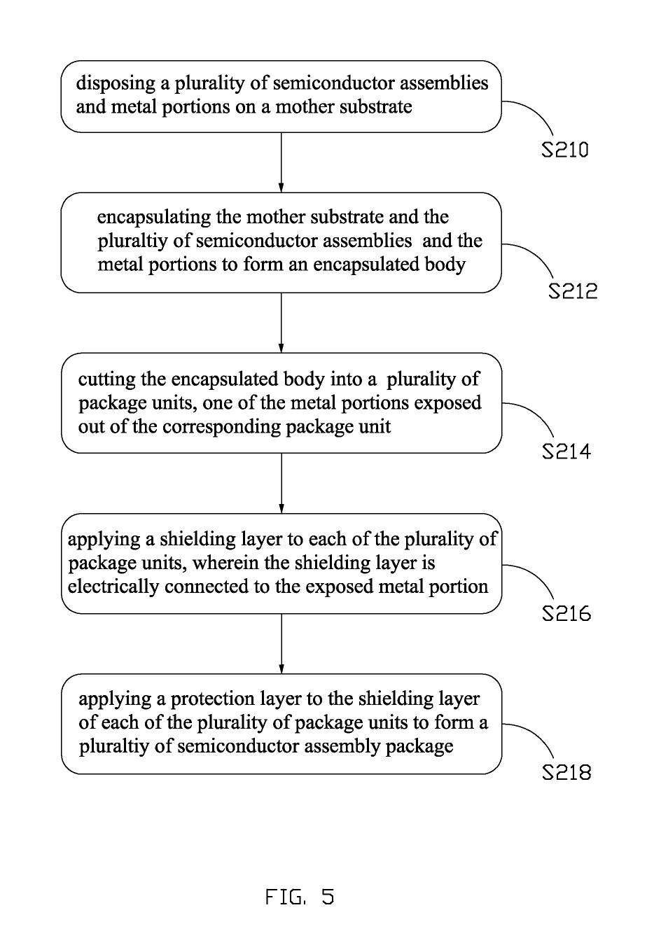

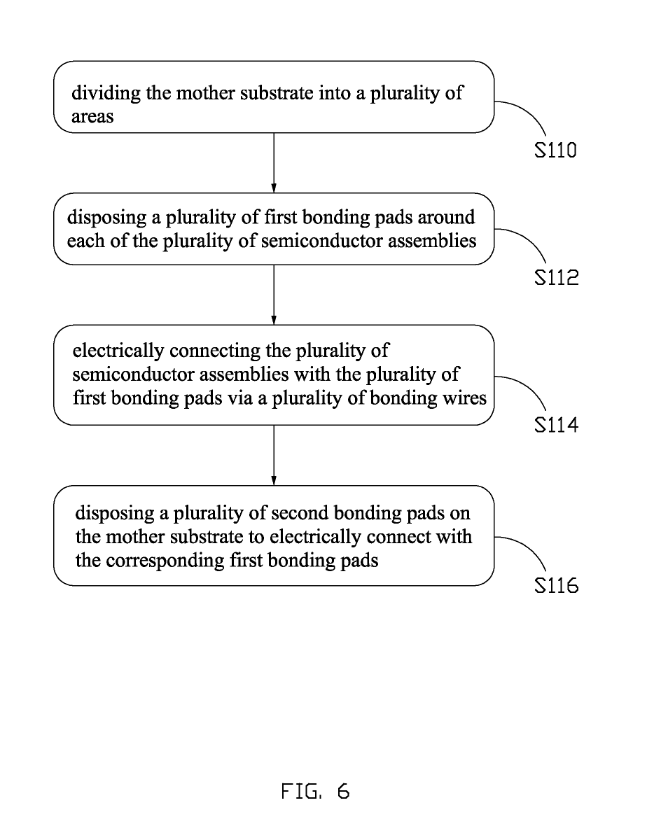

FIG. 5 is a flowchart of manufacturing the semiconductor assembly package 100 in accordance with the present disclosure, and FIG. 6 is a flowchart of disposing a plurality of semiconductor assemblies 30 on a mother substrate 200 in accordance with the present disclosure.

In block S210, the plurality of semiconductor assemblies 30 and a plurality of metal portions 27 are disposed on the mother substrate 200. In this embodiment, disposing the plurality of semiconductor assemblies 30 on a mother substrate 200 comprises steps as follow, shown in FIG. 6.

In block S110, the mother substrate 200 is divided into a plurality of areas to correspondingly place the plurality of semiconductor assemblies 30 thereon. That is, the mother substrate 200 comprises a plurality of daughter substrates 20 corresponding to the plurality of areas and each of the plurality of semiconductor assemblies 30 is disposed on and mechanically attached to the corresponding daughter substrate 20.

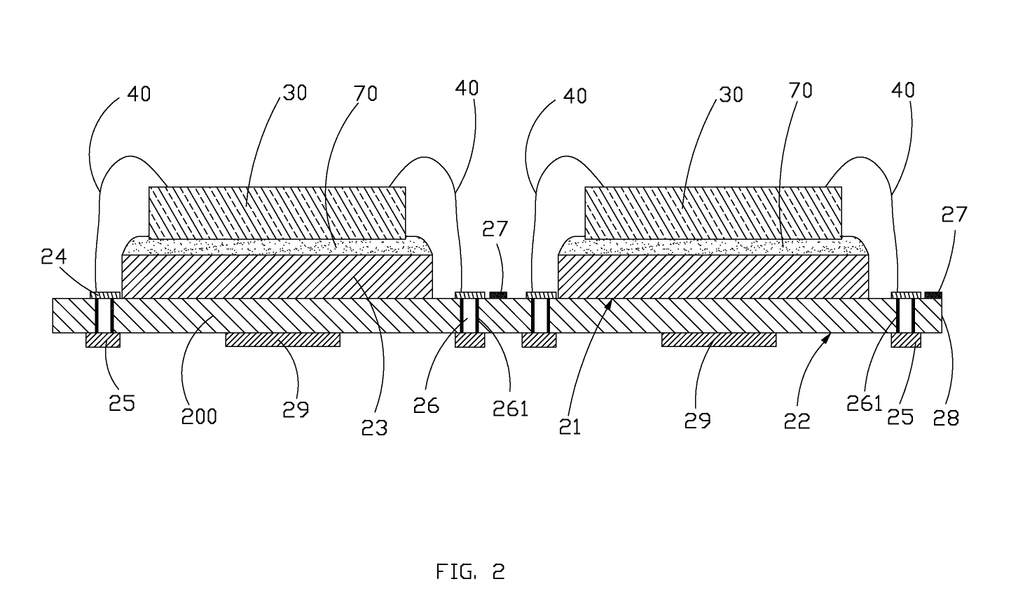

In block S112, a plurality of first bonding pads 24 are disposed around each of the plurality of semiconductor assemblies 30. As illustrated in FIG. 2, the mother substrate 200 comprises a first surface 21, a second surface 22 opposite to the first surface 21. A plurality of seat portions 23 are placed on the first surface 21 to support the corresponding semiconductor assemblies 30 on the corresponding daughter substrates 20. In the illustrated embodiment, the plurality of semiconductor assemblies 30 are electrically mounted on the corresponding seat portions 23 of the mother substrate 200 by means of an adhesive 70. The adhesive 70 may be an adhesive film, an epoxy resin, or the like, to further provide improved heat dissipation of the plurality of semiconductor assemblies 30. The plurality of first bonding pads 24 are placed on the first surface 21 around each of the plurality of semiconductor assemblies 30. Each of the plurality of semiconductor assemblies 30 may be a chip, a memory assembly, a logic assembly, and other like elements.

In block S114, the plurality of semiconductor assemblies 30 are electrically connected to the plurality of first bonding pads 24 via a plurality of bonding wires 40 so as to electrically connect to the mother substrate 200. It should be noted that each of the plurality of semiconductor assemblies 30 is grounded by connecting with one of the plurality of first bonding pads 24 which is grounded. In the illustrated embodiment, each of the plurality of bonding wires 40 is a golden wire.

In block S116, a plurality of second bonding pads 25 are disposed on the second surface 22 of the mother substrate 200 to electrically connect with the corresponding first bonding pads 24. The plurality of second bonding pads 25 are in pair with the corresponding first bonding pads 24, respectively. The mother substrate 200 defines a plurality of via holes 26 passing through the first surface 21 to the second surface 22 to electrically connect between each of the plurality of first bonding pads 24 and the corresponding second bonding pad 25. In this embodiment, a metal layer 261 (such as copper, gold or silver) is coated on inside wall of each of the plurality of via holes 26, thus, the plurality of first bonding pads 24 electrically connect to the corresponding second bonding pads 25 via the corresponding metal layers 261.

Corresponding to each of the plurality of semiconductor assemblies 30, there is one of the second bonding pads 25 electrically connecting to a grounding element, thus, one of the second bonding pads 25 is grounded and one of the first bonding pads 24 is grounded as the plurality of second bonding pads 25 are in pair with the corresponding first bonding pads 24 respectively. A plurality of connecting portions 29 are disposed on the second surface 22 of the mother substrate 200 opposite to the corresponding seat portions 23. Each of the plurality of connecting portions 29 is corresponding to each daughter substrate 20 to electrically connect to a circuit (not shown) of the mother substrate 200 as an input/output terminal of the mother substrate 200 to input/output electrical signals.

The plurality of metal portions 27 are disposed on the first surface 21 of the mother substrate 200. Each of the plurality of daughter substrates 20 has at least one metal portion 27 to electrically connect to the corresponding second bonding pad 25 which is grounded via a metal wire (not shown), so that, the plurality of metal portions 27 are grounded. In the embodiment, the plurality of metal portions 27 are made of copper foil.

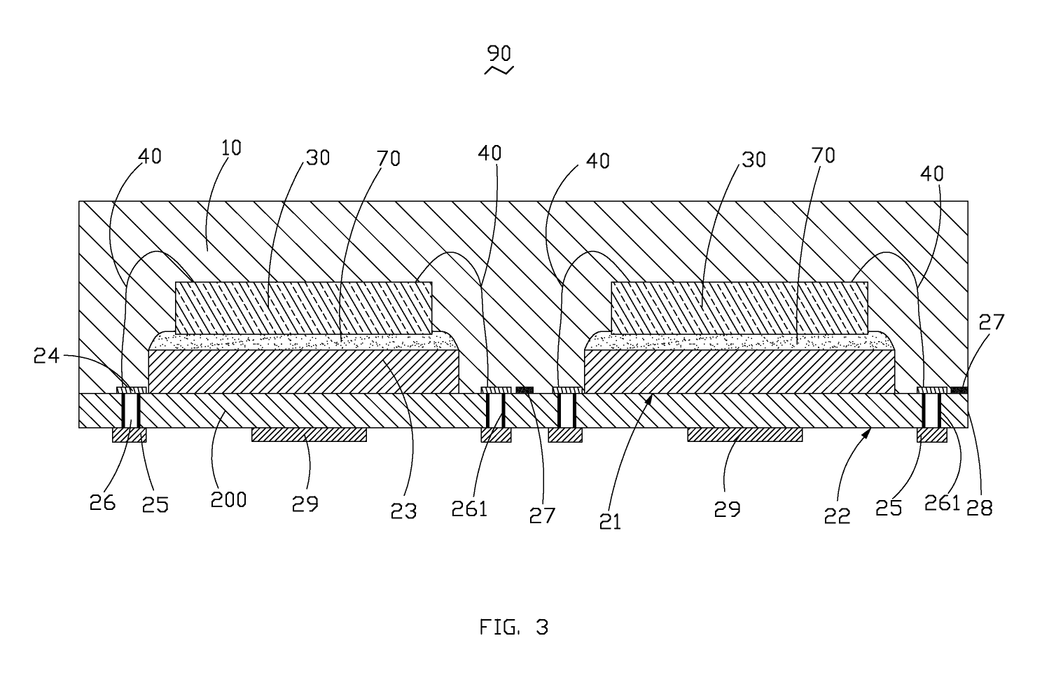

In block S212, a mold compound 10 is encapsulated on the plurality of semiconductor assemblies 30, the metal portions 27, the plurality of bonding wires 40 and the first surface 21 of the mother substrate 200 to form an encapsulated body 90. As illustrated in FIG. 3, the mold compound 10 is coated on top surfaces of the plurality of semiconductor assemblies 30 and the first surface 21. In the illustrated embodiment, the mold compound 10 is made of non-conductive material, such as black gum, plastic.

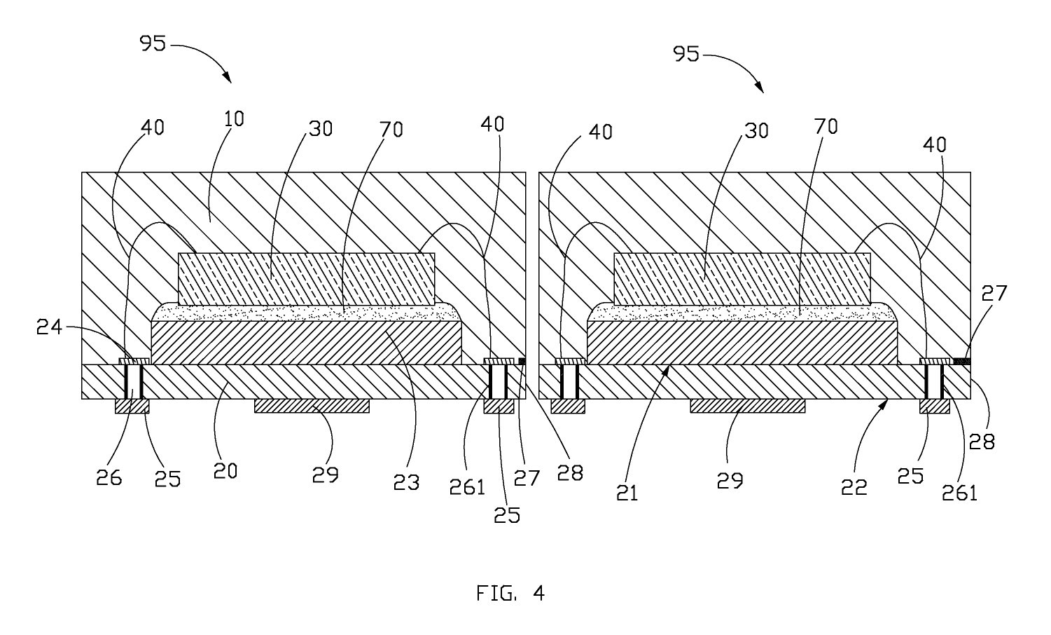

In block S214, the encapsulated body 90 is cut into a plurality of package units 95 and each of the plurality of package units 95 only comprises one of the plurality of semiconductor assemblies 30 disposed on the corresponding daughter substrate 200. As illustrated in FIG. 4, one of the metal portions 27 is exposed out of the corresponding package unit 95 on an edge side 28 of the package unit 95. As each of the daughter substrate 20 has at least one metal portion 27 electrically connected with the corresponding second bonding pad 25 which is grounded, each of the plurality of package units 95 is grounded. In other embodiment, the mother substrate 200 is a multilayer printed circuit board and the plurality of metal portions 27 are copper foil layers on any layer of the mother substrate 200, and one of the plurality of metal portions 27 is exposed on the side edge 28 and electrically connects to the second bonding pad 25 which is grounded, therefore, each of the plurality of package units 95 is grounded.

In block S216, a shielding layer 50 is applied to outer surface of each of the plurality of package units 90 to provide electromagnetic shielding for the semiconductor assembly 30. That is, the shielding layer 50 is applied to outer surface of the mold compound 10 and the side edge 28 and electrically connects to the metal portion 27 which is grounded, thus, the shielding layer 50 is grounded, as shown in FIG. 1. That is, each of the plurality of semiconductor assemblies 30 can be shielded by connecting the shielding layer 50 with the metal layer 27. In the illustrated embodiment, the shielding layer 50 is made of metal, such as copper, nickel, chrome, gold, tin, lead, bismuth, indium, silver, and combination of these metals, which can minimize EMI from the semiconductor assembly 30. The shielding layer 50 may be achieved by plating, vacuum printing, vacuum deposition, insert molding, spray coating and the like.

In block S218, a protection layer 60 is applied to outer surface of the shielding layer 50 of each of the plurality of package units 95 to form the semiconductor assembly package 100 so as to prevent short-circuit between the semiconductor assembly package 100 and other components. The protection layer 60 is made of non-conductive material, such as plastic, rubber, lacquer, glass, and the like. In the illustrated embodiment, the protection layer 60 is made of a transparent non-conductive material, such as transparent Polyvinylcloride (PVC).

Each of the semiconductor assembly package 100 is mechanically mounted on a printed circuit board (PCB) 80 (shown in FIG. 1) via the plurality of second bonding pads 25 one of which electrically connects with a grounded element (not shown) on the PCB 80, and is electrically connected with the PCB 80 via the connecting portion 29 and the plurality of second bonding pads 25 which input/output electrical signals.

The shielding layer 50 may produce a plurality of tin points adhered on the PCB 80 in soldering process, and the plurality of tin points may affect connection between the shielding layer 50 and the PCB 80. The shielding layer 50 is insulated from each of the plurality of second bonding pads 25 to avoid the plurality of tin points adhered on the PCB 80. In this embodiment, the shielding layer 50 is separate from the plurality of second bonding pads 25. In addition, the protection layer 60 is isolated from each of the plurality of second bonding pads 25 to avoid affecting the second bonding pads 25 from adhering on the PCB 80.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A method of manufacturing a semiconductor assembly package, comprising:
disposing a plurality of semiconductor assemblies and metal portions on a mother substrate;
encapsulating the mother substrate and the plurality of semiconductor assemblies and the metal portions to form an encapsulated body;
cutting the encapsulated body into a plurality of package units, wherein each of the plurality of package units comprises one of the plurality of semiconductor assemblies, a daughter substrate separated from the mother substrate, and one of the metal portions exposed out of the corresponding package unit;
applying a shielding layer to each of the plurality of package units, wherein the shielding layer is electrically connected to the exposed metal portion of the corresponding package unit; and
applying a protection layer to the shielding layer of each of the plurality of package units to form a semiconductor assembly package.

2. The method of manufacturing the semiconductor assembly package as claimed in claim 1, wherein disposing a plurality of semiconductor assemblies on a mother substrate comprises:
respectively dividing the mother substrate into a plurality of areas, and disposing each of the plurality of semiconductor assemblies on the corresponding area to mechanically attach to the mother substrate;
respectively disposing a plurality of first bonding pads around each of the plurality of semiconductor assemblies;
respectively electrically connecting the plurality of semiconductor assemblies with the plurality of first bonding pads via a plurality of bonding wires; and
respectively disposing a plurality of second bonding pads on the mother substrate to electrically connect with the corresponding first bonding pads.

3. The method of manufacturing the semiconductor assembly package as claimed in claim 2, wherein each of the plurality of package units comprises a daughter substrate, the daughter substrate comprises a first surface, a second surface opposite to the first surface, the plurality of first bonding pads are placed on the first surface, the plurality of second bonding pads are placed on the second surface and in pair with the corresponding first bonding pads.

4. The method of manufacturing the semiconductor assembly package as claimed in claim 3, wherein disposing a plurality of semiconductor assemblies on a mother substrate further comprises defining a plurality of via holes passing through the first surface to the second surface in the daughter substrate to electrically connect between each of the plurality of first bonding pads and the corresponding second bonding pad.

5. The method of manufacturing the semiconductor assembly package as claimed in claim 4, wherein one of the plurality of second bonding pads electrically connects to a grounded element so as to be grounded.

6. The method of manufacturing the semiconductor assembly package as claimed in claim 5, wherein the metal portion is disposed on the first surface and electrically connects to the second bonding pad which is grounded.

7. The method of manufacturing the semiconductor assembly package as claimed in claim 6, wherein further provides a plurality of bonding wires electrically connecting each of the semiconductor assembly to the plurality of first bonding pads, and each of the semiconductor assembly is grounded by connecting with one of the plurality of first bonding pads to the corresponding second bonding pads which is grounded.

8. The method of manufacturing the semiconductor assembly package as claimed in claim 3, wherein the shielding layer is insulated from the plurality of second bonding pads.

9. The method of manufacturing the semiconductor assembly package as claimed in claim 3, wherein a plurality of seat portions are placed the first surface, the plurality of semiconductor assemblies are electrically mounted on the corresponding seat portions by means of an adhesive.

10. The method of manufacturing the semiconductor assembly package as claimed in claim 9, wherein a plurality of connecting portions are disposed on the second surface opposite to the corresponding seat portions to electrically connected to the corresponding daughter substrates.

11. A semiconductor assembly package, comprising:
a package unit, comprising:
a daughter substrate, comprising a metal portion grounded;
a semiconductor assembly, disposed on and electrically connected to the daughter substrate; and
a mold compound encapsulating the semiconductor assembly and the daughter substrate, wherein the metal portion is exposed out of the package unit;
a shielding layer applied to the package unit and electrically connected to the metal portion, to provide electromagnetic shielding for the semiconductor assembly; and
a non-conductive protection layer covered on the shielding layer.

12. The semiconductor assembly package as claimed in claim 11, wherein the daughter substrate comprises a first surface, a second surface opposite to the first surface, a plurality of first bonding pads placed on the first surface and a plurality of second bonding pads placed on the second surface in pair with the plurality of first bonding pads.

13. The semiconductor assembly package as claimed in claim 12, wherein the daughter substrate defines a plurality of via holes passing through the first surface to the second surface to electrically connect between each of the plurality of first bonding pads and the corresponding second bonding pad as a metal layer is coated on inside wall of each of the plurality of via holes.

14. The semiconductor assembly package as claimed in claim 13, wherein the daughter substrate is electrically mounted on a printed circuit board (PCB) via the plurality of second bonding pads one of which electrically connects to a grounded element on the PCB.

15. The semiconductor assembly package as claimed in claim 14, wherein the metal portion is disposed on the first surface and electrically connects to the second bonding pad which is grounded.

16. The semiconductor assembly package as claimed in claim 15, wherein the shielding layer is insulated from the plurality of second bonding pads.

17. The semiconductor assembly package as claimed in claim 12, wherein the daughter substrate comprises a seat portion placed on the first surface of the daughter substrate, the semiconductor assembly is electrically mounted on the seat portion by means of an adhesive.

18. The semiconductor assembly package as claimed in claim 17, wherein the daughter substrate comprises a connecting portion disposed on the second surface of the daughter substrate opposite to the seat portion and electrically connected to the daughter substrate with the PCB.

19. The semiconductor assembly package as claimed in claim 12, wherein further comprises a plurality of bonding wires electrically connecting the semiconductor assembly to the plurality of first bonding pads.

20. The semiconductor assembly package as claimed in claim 19, wherein the semiconductor assembly is grounded by connecting with one of the plurality of first bonding pads to the corresponding second bonding pads which is grounded.
